(19) United States
(12) Patent Application Publication
(10) Pub. No.: US 2012/0008299 A1
(43) Pub. Date: Jan. 12, 2012

(54) SYSTEM AND APPARATUS FOR PROTECTING A MOBILE DEVICE

(76) Inventor: David Gengler, Draper, UT (US)

(21) Appl. No.: 12/832,845

(22) Filed: Jul. 8, 2010

(51) Int. Cl. H05K 7/02; H05K 5/02

(52) U.S. Cl. 361/807; 361/679.01

(57) ABSTRACT

A system and apparatus providing protection and functionally for mobile devices by providing a protective cover, a variable angle stand, and a more convenient user input device.

### CROSS-REFERENCE TO RELATED APPLICATIONS

Not Applicable.

### STATEMENT REGARDING FEDERALLY SPONSORED RESEARCH OR DEVELOPMENT

### Not Applicable.

### BACKGROUND

1. The Field of the Disclosure

The disclosure relates to electronic mobile devices and providing protection for them from everyday wear to more extreme accidental situations. More specifically, the disclosure relates to protecting mobile devices with a relatively large display and touch screen functionality.

2. Description of Related Art

The current protective devices are often inadequate to fully protect an expensive mobile device. A damaged mobile device could mean data loss and unnecessary expense to the user. Some current protective devices are visually pleasing or provide increased gripping. However, most current protective devices rely on the mobile device to provide structural integrity, often merely being nothing more than expensive scratch protectors. Many allow easy access to the display, which can also allow easy exposure to damage and danger. Other problems with current devices is that they can make using the mobile device more cumbersome either by making the control areas hard to reach or by preventing secure tactile holding.

Despite the advantages of known mobile device protectors, improvements are still being sought and the prior art is thus characterized by several disadvantages that are addressed by the disclosure. The disclosure minimizes, and in some aspects eliminates, the above-mentioned failures, and other problems, by utilizing the apparatus and system features described herein.

The features and advantages of the disclosure will be set forth in the description which follows, and in part will be apparent from the description, or may be learned by the practice of the disclosure without undue experimentation. The features and advantages of the disclosure may be realized and obtained by means of the features and combinations particularly pointed out in the appended claims.

### SUMMARY

One problem commonly encountered by mobile devices is damage to the device itself either because no protective device is used or because the protective device used was ineffective. Accordingly, if a protective device inhibits usability it will not be used. What is needed is a protective device that also increases the functionality of a mobile device.

The disclosure addresses these and other problems by providing a structurally sound protective device that complements the features and functions of the mobile device.

For example, in order for the protective device to fully protect the functionality of the mobile device it must provide its own structural integrity. Accordingly, the protective device disclosed herein may comprise a form factor similar to a mobile device to be protected wherein the protector may be configured such that the mobile device nests into the protector and may, thus, have a shell constructed of a substantially rigid material. The embodiment may also have a configuration such that the face or display of the mobile device is covered and may have a shock absorbing layer, but provides openings to allow electronic connections to be made to the device.

In an embodiment the shock absorbing layer may also be configured to prevent scratches or breakage on the mobile device. A suitable material for the shock absorbing layer may be neoprene or a foam material.

In an embodiment the protective device might have a shell made from a metal, such as aluminum, and may have other rigid features, such as a stand built-in, which positions the mobile device in a plurality of positions or angles for optimal use.

An embodiment of the protective device may be configured to be moved from covering the face or display of the mobile device to the back of the mobile device so that the mobile device can be used. It may also be attached to the back of the mobile device for storage so that the protective device does not become lost from being set down while the device is being used.

An embodiment may comprise a stand built into the protective device so that the mobile device can be viewed from the proper viewing angle during use, such that the device may be located or positioned in a plurality of positions or angles relative to the stand. The stand may be attached to the shell of the protective device and may have a combination of rigid and flexible portions to allow the stand to be folded.

An embodiment may have more than one stand structure built into the protective device, thereby allowing a user to select differing angles during use. The plurality of stand structures may nest within each other and share a common hinge. The plurality of stand structures may also be disposed opposite each other in the protective device so as to allow the full width of the stand to be used for both structures thereby increasing the strength.

In an embodiment the protective device may have a slot recessed into either the shell or the shock absorbing layer to allow a stand structure to be folded and tucked back into the protective device in a substantially flush manner.

In an embodiment the protective device may provide additional input devices for the mobile device to improve the functionality of the mobile device. The input device may be a keyboard that is fixed within the protective device. The shell or shock absorbing layer may be provided with a recess to accommodate the keyboard therein. The shell may also be provided with higher walls to accommodate the input device.

In an embodiment the protective device may provide an electronic connection or a wireless connection between an input device and the mobile device. Such an embodiment may also provide a slot recessed into the shock absorbing layer to allow the electronic connector to be tucked out of the way.

The protective device may be bundled with a mobile device for convenience at the time of purchase. An embodiment of such a system would include a mobile device therein and the above features would be tailored to the included mobile device.

### BRIEF DESCRIPTION OF THE DRAWINGS

These and other features and advantages of the disclosure will now be described with reference to the drawings of certain preferred embodiments, which are intended to illustrate and not to limit the disclosure, and in which:

FIG. 1 illustrates an embodiment of a popular type of mobile device nested within a protective device.

FIG. 2 illustrates an embodiment of a mobile device nested within a protective device when the mobile device is not being used.

FIG. 3 illustrates an embodiment of a mobile device nested within a protective device when the mobile device is being used.

FIG. 4 illustrates an embodiment of a mobile device being elevated by integrated stands.

FIG. 5 illustrates an embodiment of a mobile device protector in the closed position.

FIG. 6 illustrates an embodiment wherein a mobile device is being elevated by integrated stands.

FIG. 7 illustrates an embodiment wherein a mobile device is being elevated by integrated stands at a reduced angle.

FIG. 8 illustrates an embodiment wherein a mobile device is being elevated by integrated stands at an angle and having an improved user input device.

FIG. 9 illustrates an embodiment of a mobile device protector having an improved user input device.

FIG. 10 illustrates an embodiment wherein a mobile device is being elevated by integrated stands at an angle and is having an improved user input device.

FIG. 11 illustrates an embodiment wherein a mobile device is being elevated by integrated stands at an angle, and includes an improved user input device that is connected to the mobile device.

FIG. 12 illustrates an embodiment wherein a mobile device protector is configured with a plurality of stands in opposing positions, particularly the stands are each illustrated in an open position.

FIG. 13 illustrates an embodiment wherein a mobile device protector is configured with a plurality of stands in opposing positions, particularly the stands are each illustrated in a closed position.

FIG. 14 illustrates an embodiment wherein a plurality of viewing angles of a mobile device are shown by the adjustment of the mobile device relative to the stand or support structure.

FIG. 15 is a front view of an embodiment illustrating the mobile device protector 205, including the stand or support structure, that may be used to support the mobile device 211 either in landscape mode or portrait mode.

### DETAILED DESCRIPTION

For the purposes of promoting an understanding of the principles in accordance with the disclosure, reference will now be made to the embodiments illustrated in the drawings and specific language will be used to describe the same. It will nevertheless be understood that no limitation of the scope of the disclosure is thereby intended. Any alterations and further modifications of the inventive features illustrated herein, and any additional applications of the principles of the disclosure as illustrated herein, which would normally occur to one skilled in the relevant art and having possession of this disclosure, are to be considered within the scope of the disclosure claimed.

It must be noted that, as used in this specification and the appended claims, the singular forms “a,” “an,” and “the” include plural referents unless the context clearly dictates otherwise.

In describing and claiming the disclosure, the following terminology will be used in accordance with the definitions set out below.

As used herein, the terms “comprising,” “including,” “containing,” “characterized by,” and grammatical equivalents thereof are inclusive or open-ended terms that do not exclude additional, unrecited elements or method steps.

As used herein, the phrase “consisting of” and grammatical equivalents thereof exclude any element, step, or ingredient not specified in the claim.

As used herein, the phrase “consisting essentially of” and grammatical equivalents thereof limit the scope of a claim to the specified materials or steps and those that do not materially affect the basic and novel characteristic or characteristics of the claimed disclosure.

Embodiments of a system and apparatus which represent examples of the application of the disclosure will now be described with reference to the drawings. Variations to this system and apparatus which represent other embodiments will also be described.

For purposes of illustration, the embodiment will be described in the context of the mobile device protector in use or in condition for use. The details of the embodiments and of this specific implementation may be set forth in order to illustrate, and not to limit, the disclosure. The scope of the disclosure is defined only by the appended claims.

Although this disclosure has been described in terms of certain embodiments, other embodiments that may be apparent to those of ordinary skill in the art, including embodiments that do not provide all of the features and advantages set forth herein, may be also within the scope of this disclosure. Accordingly, the scope of the disclosure is defined only by reference to the appended claims.

It is to be understood that the above-described arrangements are only illustrative of the application of the principles of the disclosure. Numerous modifications and alternative arrangements may be devised by those skilled in the art without departing from the spirit and scope of the disclosure and the appended claims are intended to cover such modifications and arrangements. Thus, while the disclosure has been shown in the drawings and described above with particularity and detail, it will be apparent to those of ordinary skill in the art that numerous modifications, including, but not limited to, variations in size, materials, shape, form, function and manner of operation, assembly and use may be made without departing from the principles and concepts set forth herein.

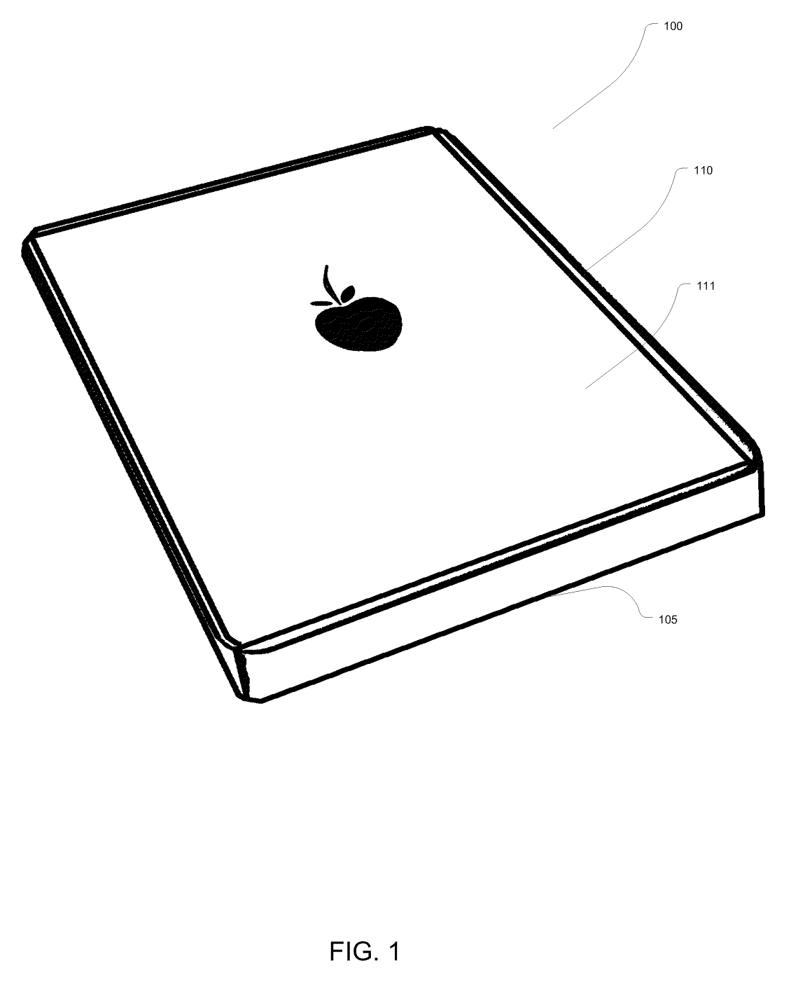

With reference to FIGS. 1-3, an embodiment of a mobile device and mobile device protector will be discussed. Illustrated in FIG. 1 is a mobile device and mobile device protector system 100. The system 100 may comprise a protector 105 and a mobile device 111 to be protected. As can be seen in FIG. 1, the protector 105 is covering the face or display portion of a mobile device 111. For illustration purposes, a logo has been placed on the back of the mobile device 111 so that the back of the device can be readily identified in the figures.

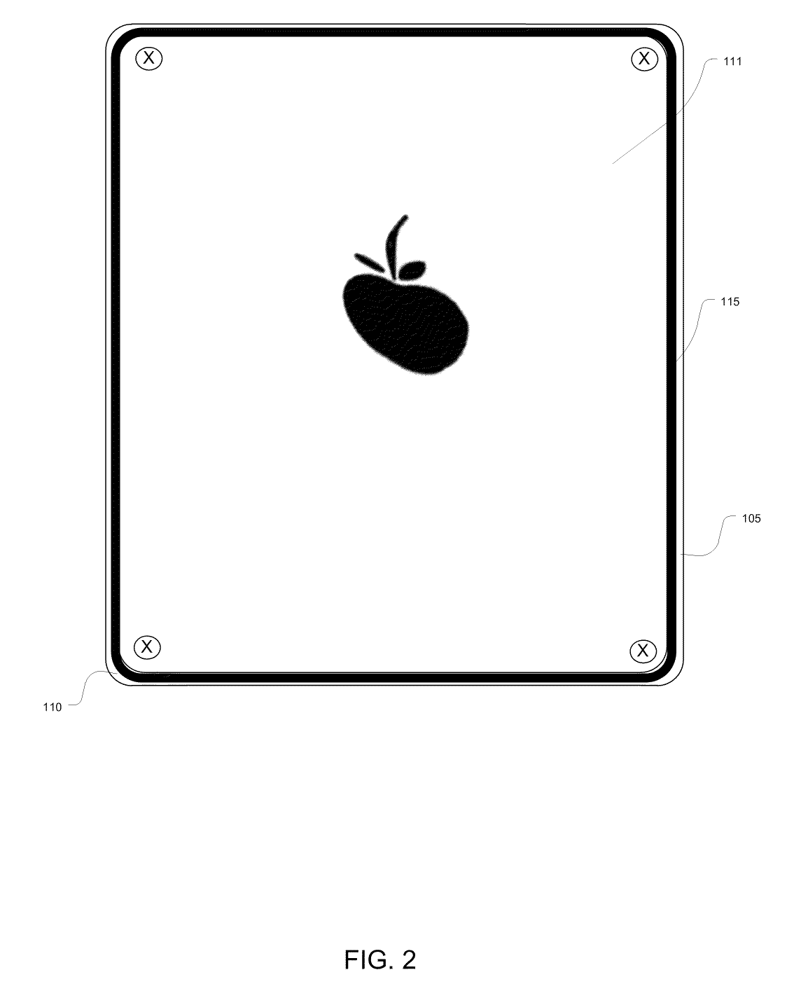

FIG. 2 illustrates how similar the dimensions are as between the mobile device 111 and the protector 105. The dimensional similarity provides a protector 105 that is not overly bulky and will not increase the size of the system 100 significantly. Also the shape of the protector 105 and the shape of the mobile device 111 are similar, again reducing the bulk of the system 100. Additionally, because the shape and size are similar a friction fit is possible wherein no additional latches or attachment means need be used. Also facilitating the friction fit between the components of the system 100 is the presence of a shock absorption layer 115.

Shock absorption layer 115 may be configured to prevent damaging forces from being transferred from the protector 105 to the mobile device 111. The shock absorption layer 115 may be of a resilient compressible material, such as neoprene or a foam material, thereby providing a bias force holding the components together through friction. The shock absorption layer 115 may also be designed to refract any impact forces so that only a fraction of the original force is transmitted to the mobile device 111. By selecting a material having significantly differing transmissive properties from the materials making up the protector 105 and mobile device 111, fractional amounts of any impact force will be dissipated at the transitional boundaries between components of the system 100. Additionally, the shock absorption layer 115 may be configured to dissipate forces internally by the nature of the material chosen. Other material suitable for the shock absorption layer 115, for example may be; leather, foam, rubber, felt and the like.

Because the shock absorption layer 115 is in contact with the mobile device 111 it may be desirable for the layer to protect the device 111 from scratches or breakage. Accordingly, the shock absorption layer 115 may comprise a soft anti scratch or anti breakage component or sub-layer. The shock absorption layer 115 may be of a homogeneous material or may be a composite of differing materials.

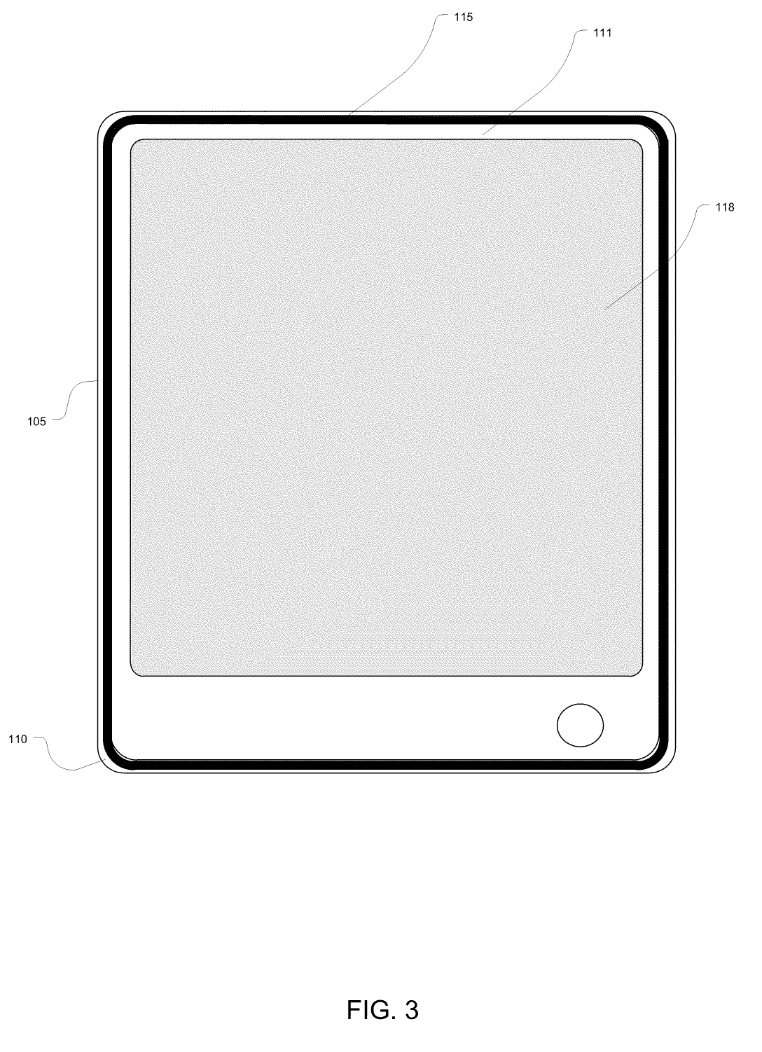

FIG. 3 illustrates the system 100 and its components in a ready state for use. As can be seen in the figure, the protector 105 has been attached to cover the back of the mobile device 111 so that the mobile device display 118 is facing outward ready for use. Protector 105 may comprise a substantially rigid shell 110. By having a rigid shell 110 the protector 105 is structurally sound and capable of holding its own shape when exposed to expected forces. The rigid shell 110 also allows the protector 105 to exert a retentive force into the system 100 such that the components of the system are able to remain affixed one to another. Additionally, the shell 110 may be able to withstand typical forces exerted on the system 100 because of its rigid properties. Many mobile devices today have aluminum components because it is light, rigid, and corrosion resistant. It is also aesthetically pleasing. Likewise, the shell 110 may be constructed of aluminum. The shell 110 may be made of a homogeneous material or may be a composite of many materials. Example, of other materials that may be used are; steel, fiber glass, carbon fiber, titanium, plastic, and the like.

The shock absorption layer 115 may be attached inside the shell 105 with adhesives or may stay in due to any resilient qualities it may possess. The shock absorption layer 115 may cover all of the interior of the shell 105 or may only be applied to portions.

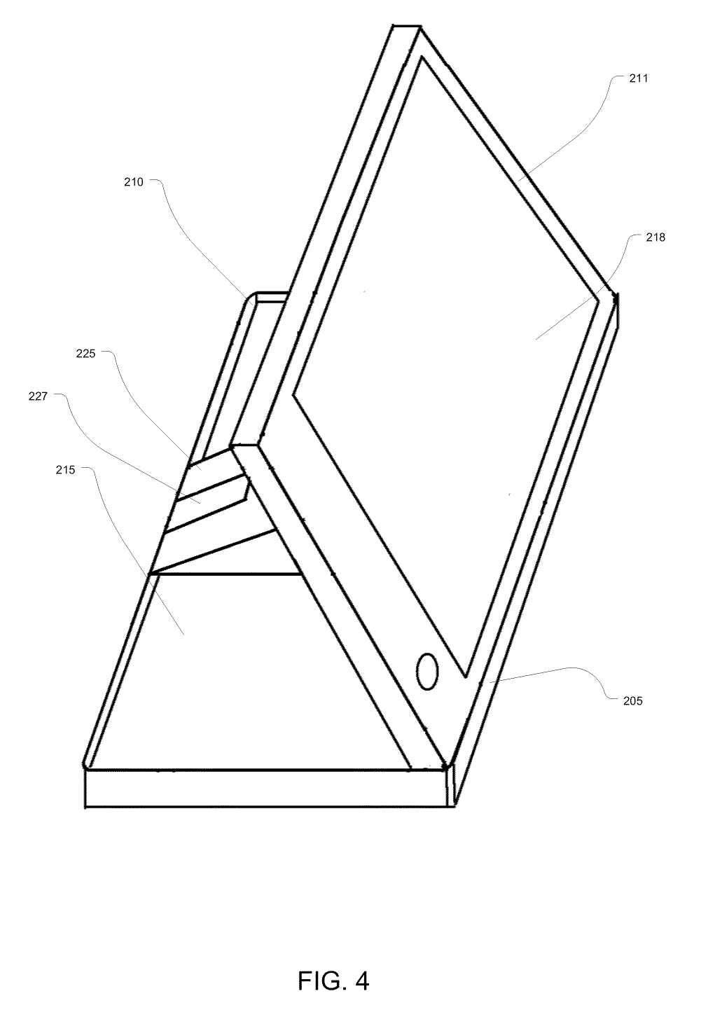

With reference to FIGS. 4-6, those figures illustrate an embodiment of a mobile device and mobile device protector ready for use. Illustrated in FIG. 4 is a mobile device and mobile device protector system 200 having a stand 225 therein. The system 200 may comprise a protector 205 and a mobile device 211 to be protected. As can be seen in the figure, the mobile device 211 is propped up on a stand structure 225 like a kick stand. The stand 225 may hold the mobile device 211 at a predetermined angle so as to improve the usability of the mobile device 211. A secondary stand 227 may be employed to provide a second angle of view. In the embodiment the second stand 227 is nested within the first stand 225 and share a hinge and axis of rotation.

The adjustment of the distance between, or tilting of, the base of the mobile device and the stand 225 may allow a viewing angle between about twenty-five and about ninety degrees. While the small or secondary stand 227 may be primarily used for typing and may allow for fewer angle options than the first stand 225 for the device 211, the larger or first stand 225 allows for multiple angles for the device 211 from its greater radial reach.

For instance, when the device 211 bottom or base is up against the larger stand 225, the device may be at about a 90 degree angle. However, in addition to this 90 degree angle, the angle of the device 211 may be infinitely variable between that position and when the bottom or base of the device 211 finally hits the edge of the case, which may be about twenty-five degrees. In other words, the large stand 225 may allow the device to be placed at a comfortable angle between about ninety degrees and about twenty-five degrees by varying the distance between the bottom or base of the mobile device 211 and the stand 225. The stands may be made having substantially rigid portion 242 and a substantially compliant portion 244. The rigid portion supplies enough support to hold the mobile device 211 in place. The compliant portion 244 allows for the adjustability of rigid portion 242 and restrains the stand from rotating too far.

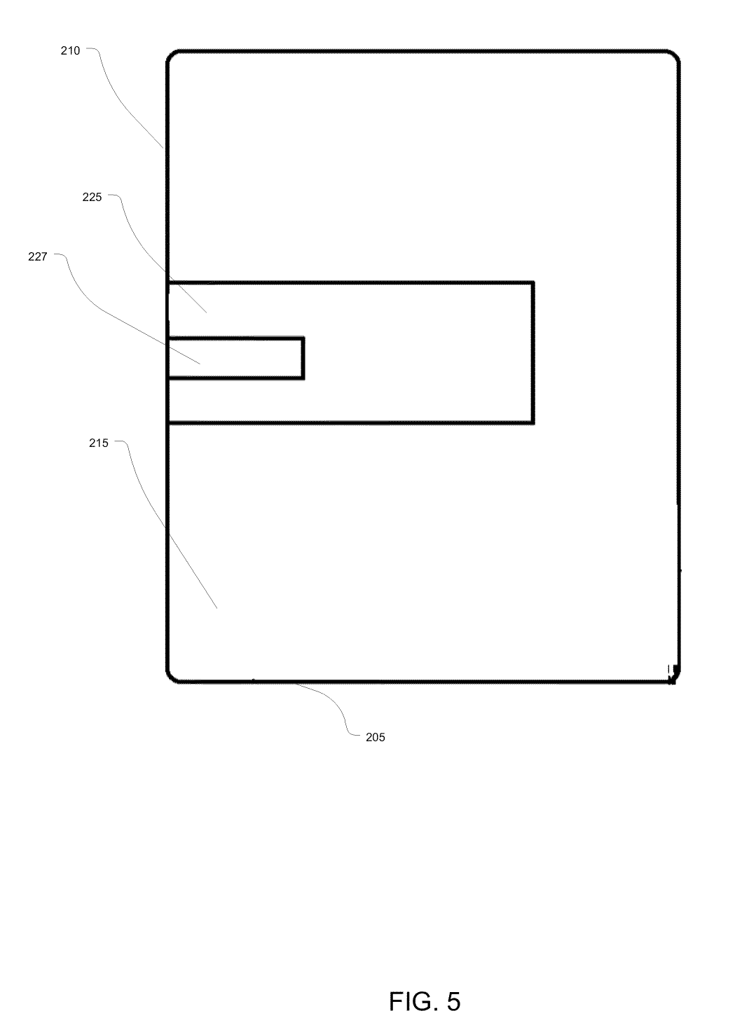

FIG. 5 illustrates a collapsed protector 205 without the presence of the mobile device 211 wherein the stand 225 is in the folded down position.

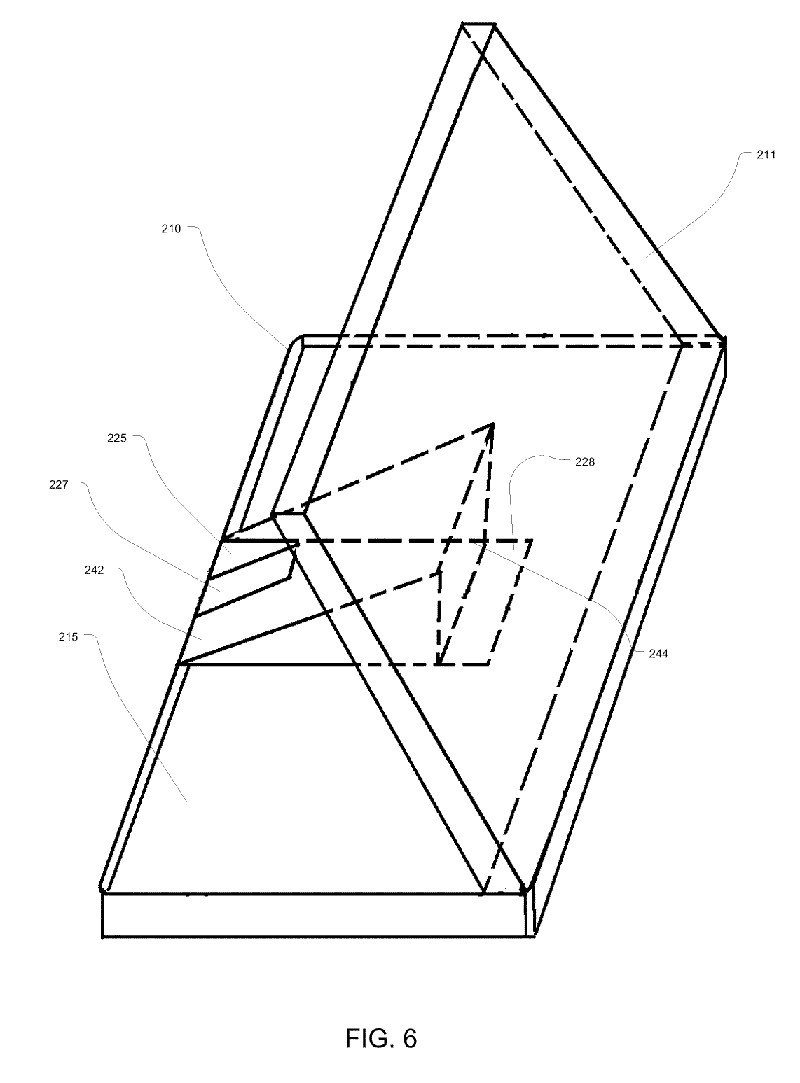

FIG. 6 illustrates the system 200 and its components in a ready state for use and propped up to a viewing angle. As can be seen in the figure, the stand 225 abuts against the back of the mobile device 211 to prop it up into position. A recessed slot 228 in the shock absorption layer 215 allows for the stand 225 to be folded down flush with the shock absorption layer 215.

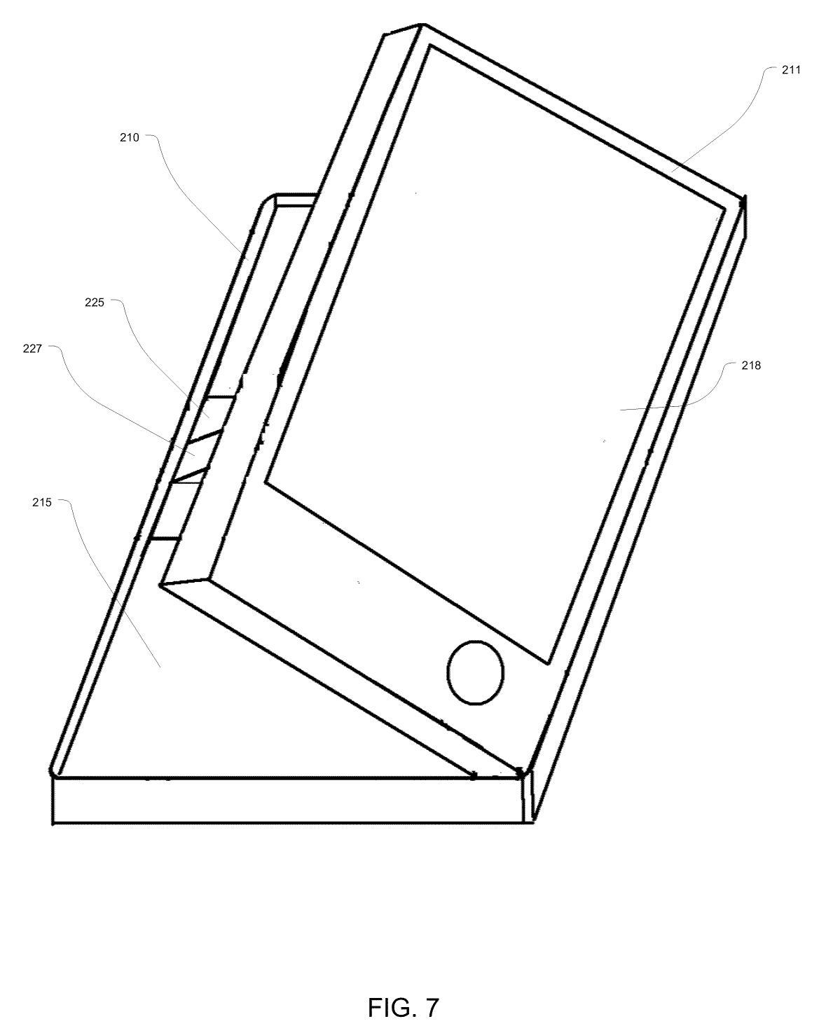

FIG. 7 illustrates the viewing angle change when the second stand 227 is used. The second viewing angle may be appropriate when using a touch screen keyboard on the mobile device 211.

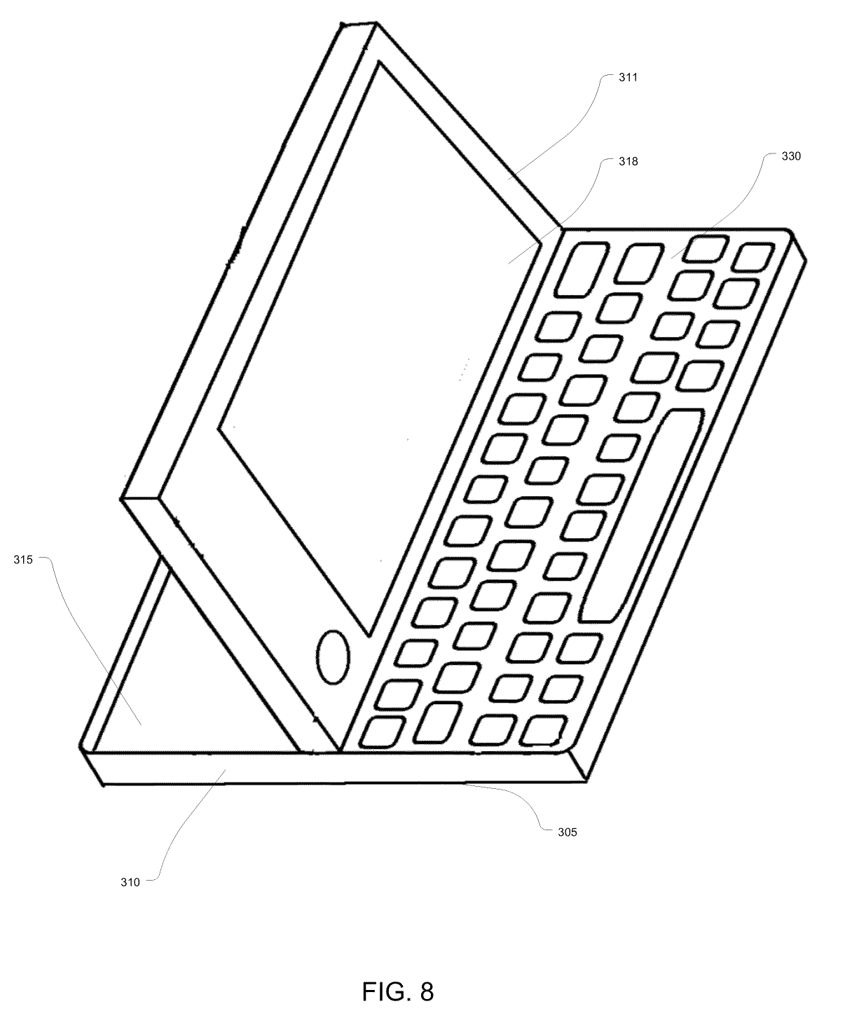

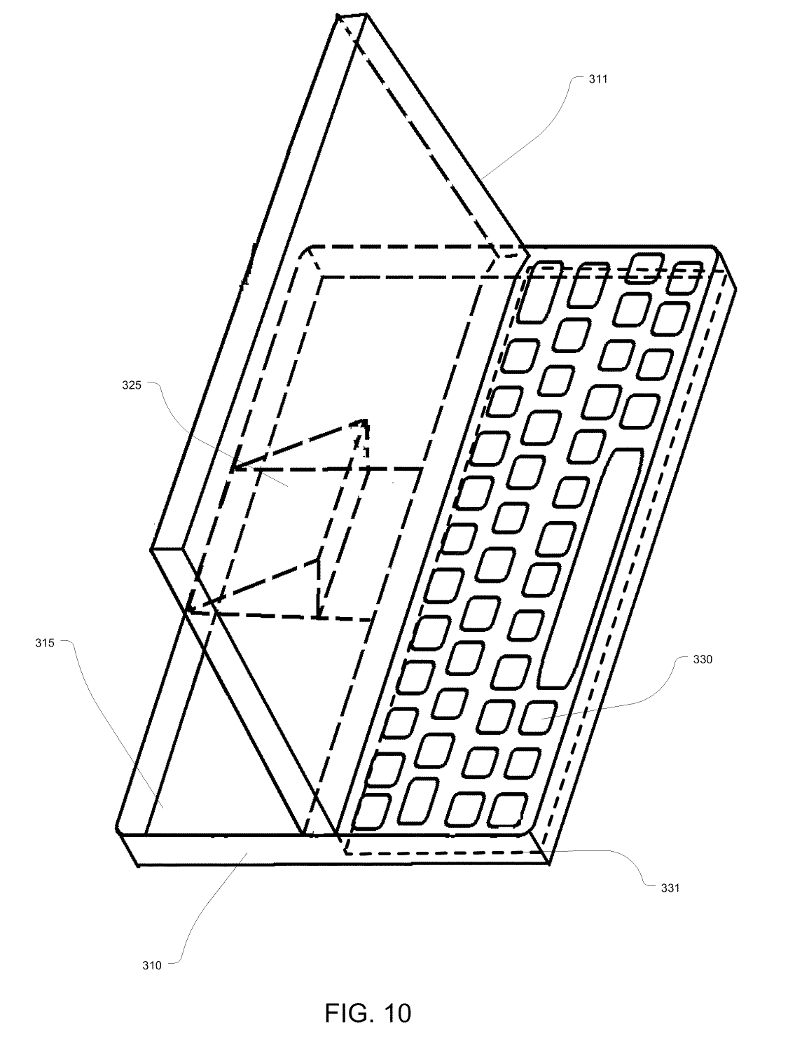

With reference to FIGS. 8-11, the figures illustrate an embodiment of a mobile device and mobile device protector ready for use having an improved input device. Illustrated in FIG. 8 is a mobile device and mobile device protector system 300 having a stand 325 and improved input device therein. The system 300 may comprise a protector 305 and a mobile device 311 to be protected. As can be seen in the figure, the mobile device 311 is propped up on a stand structure 325 like a kick stand. The stand 325 may hold the mobile device 311 at a predetermined angle so as to improve the usability of the mobile device 311. The tilting of the device relative to the stand, or adjusting the distance between the bottom or base of the device and the stand, may allow a viewing angle between about twenty-five and about ninety degrees. Further illustrated in the figure is the presence of an improved input device, in this embodiment it is a keyboard 330. Touch screen keyboards often lack the feel and efficiency of a regular tactile keyboard. As seen in FIG. 10, a recessed keyboard slot 331 in the shock absorption layer 315 allows for the keyboard 330 to rest flush with the shock absorption layer 315. The keyboard 330 may be connected to the mobile device 311 wirelessly, such as BlueTooth technology, or other wireless transmission.

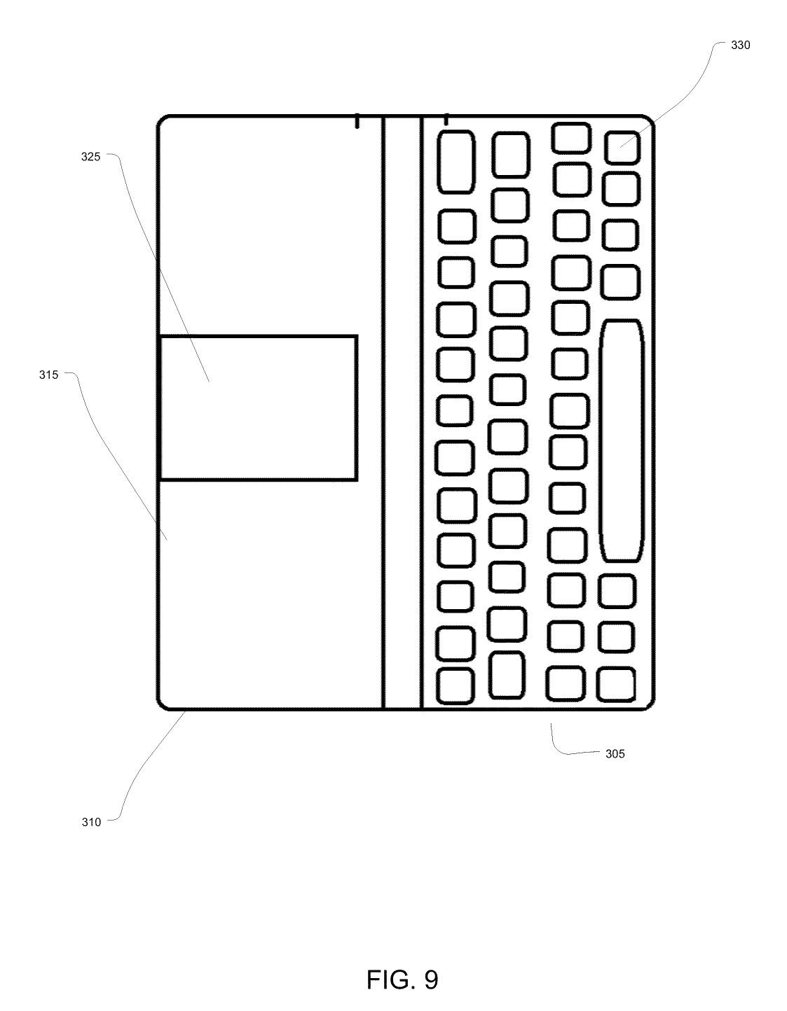

FIG. 9 illustrates a protector 305 without the presence of the mobile device 311 wherein the keyboard 330 is in position and the stand 325 is folded down in the collapsed position.

FIG. 10 illustrates the system 300 and its components in a ready state for use and propped up to a viewing angle. As can be seen in the figure, the stand 325 abuts against the back of the mobile device 311 to prop it up into position. A recessed slot 328 in the shock absorption layer 315 allows for the stand 325 to be folded down flush with the shock absorption layer 315.

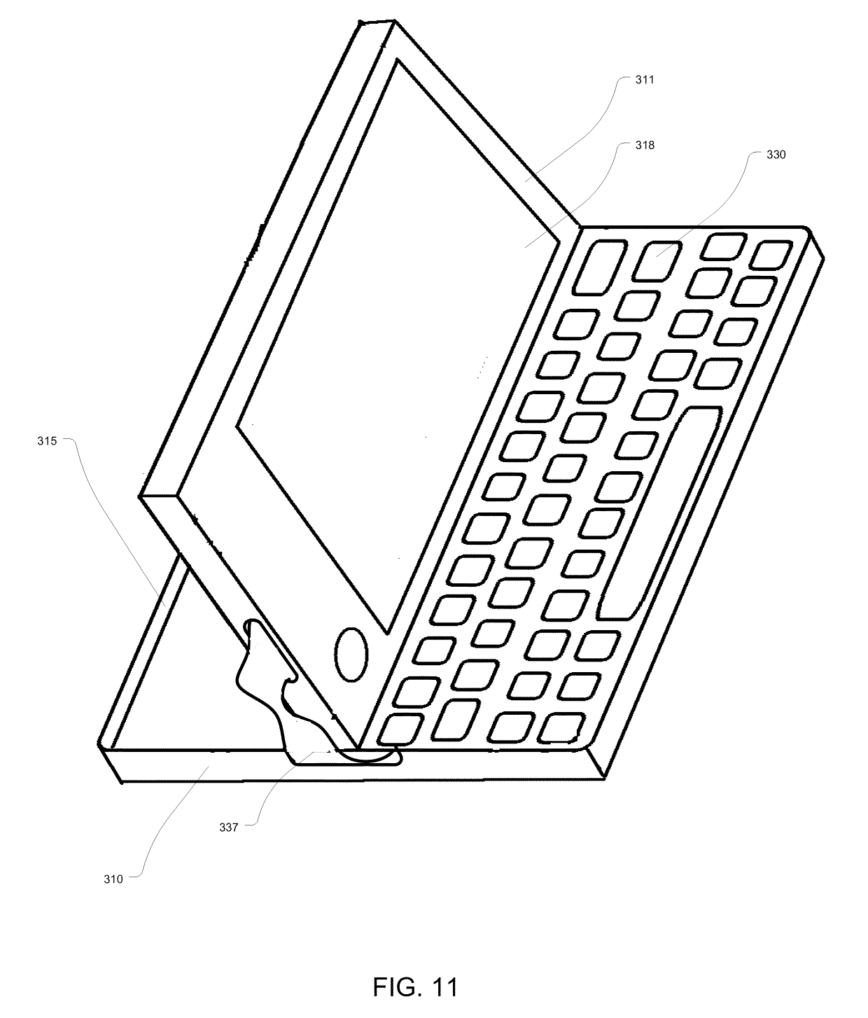

FIG. 11 illustrates the system 300, wherein the keyboard 330 is connected to the mobile device 311 by connector 337. The keyboard 330 may be battery power or electrically connected to and powered by the mobile device by an appropriate connector. The keyboard 330 may be permanently affixed to the protector 305 or may be removable. The keyboard may be powered by the mobile device 311 or may have its own power source.

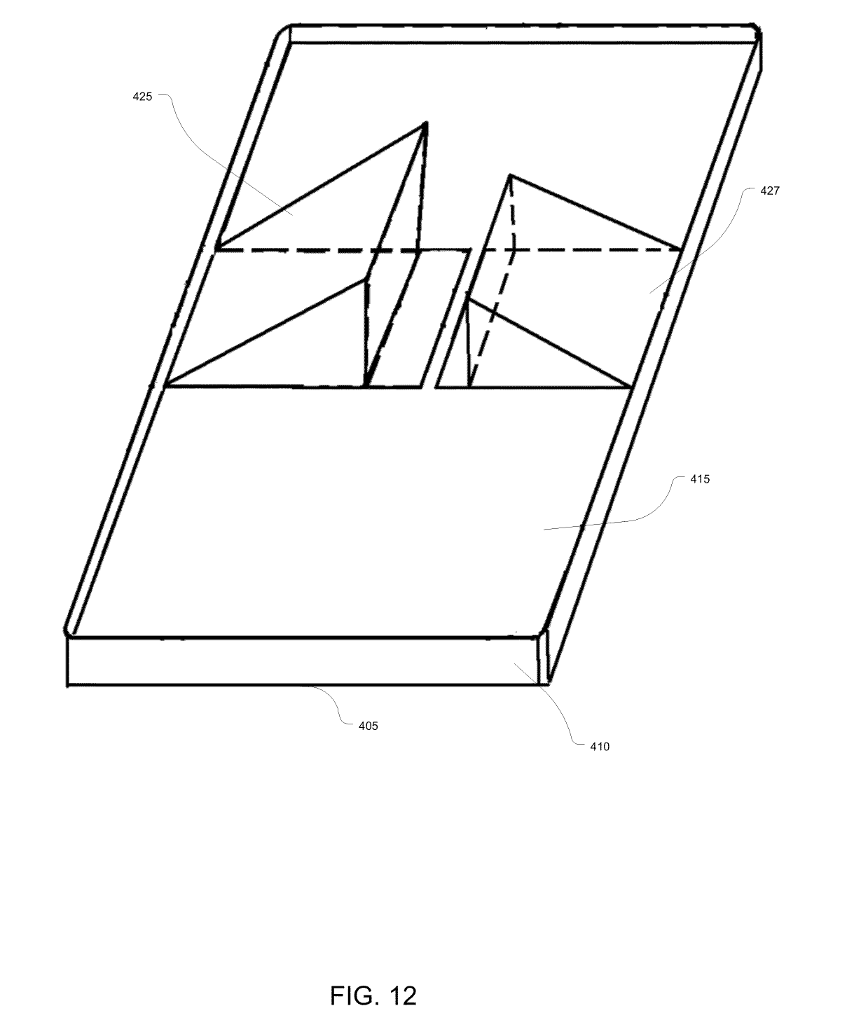

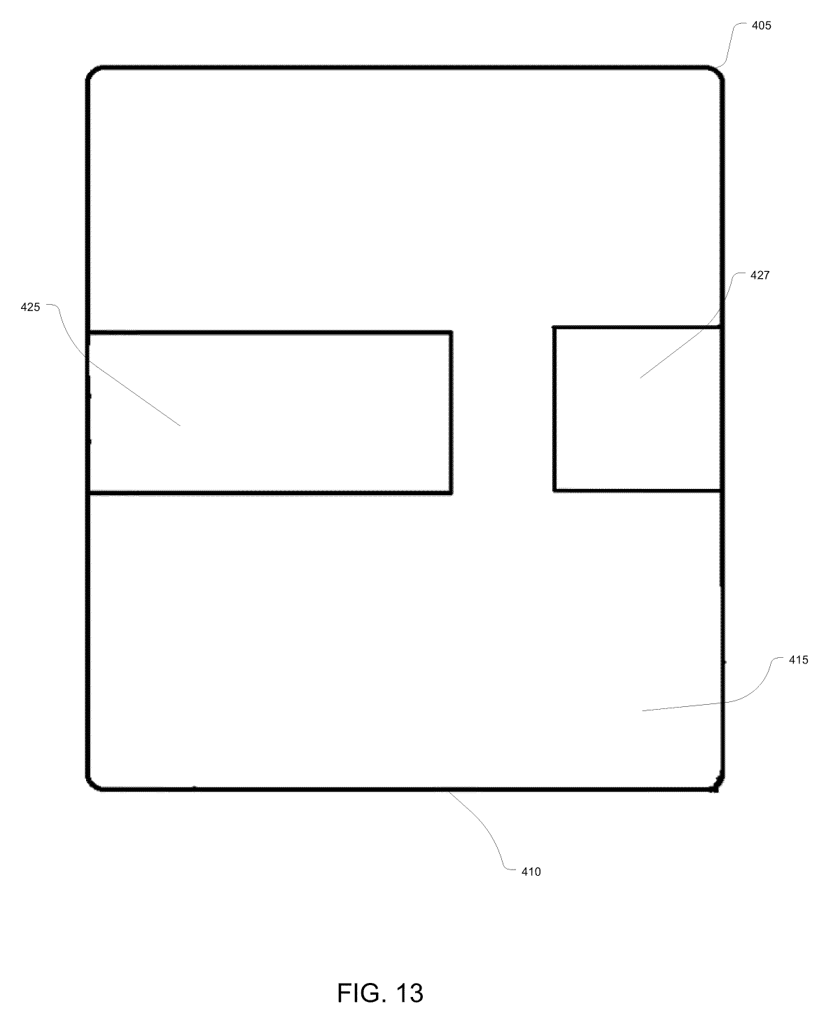

FIG. 12 illustrates an embodiment of a protector 405 having a first stand 425 and a second stand 427 disposed opposite each other with in the protector 405. FIG. 13 illustrates an embodiment of a protector 405 with opposing stands in the folded down collapsed position.

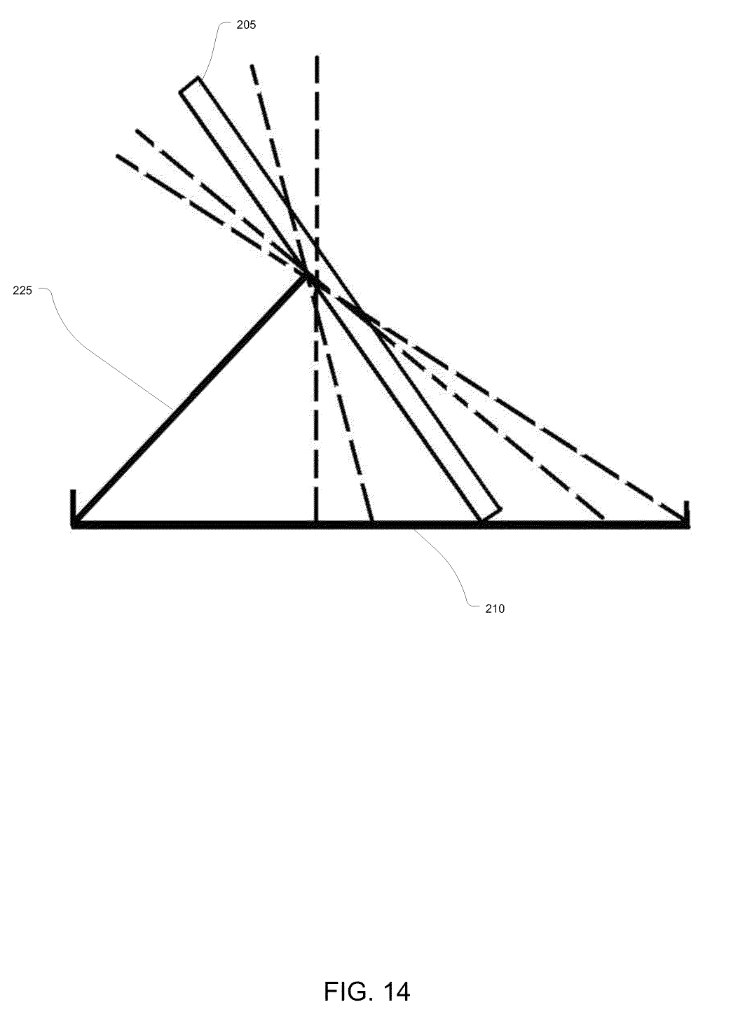

FIG. 14 illustrates an embodiment wherein a plurality of viewing angles of a mobile device are shown by the adjustment of the distance between, or tilting of, the base of the mobile device relative to the support structure or stand. As discussed above with respect to FIGS. 4-6, the larger or first stand allows for multiple angles for viewing the device by varying its greater radial reach. For instance, when the device bottom is up against the larger stand, the device may be at a 90 degree angle. However, in addition to this 90 degree angle, the angle of the device is infinitely variable between there and when the bottom finally hits the edge of the case, which may be about twenty-five degrees. In other words, the large stand allows for the device to be placed at a comfortable angle between about ninety degrees and about twenty-five degrees by adjusting the distance between, or tilting, the base of the mobile device and the first stand by varied amounts as illustrated in FIG. 14.

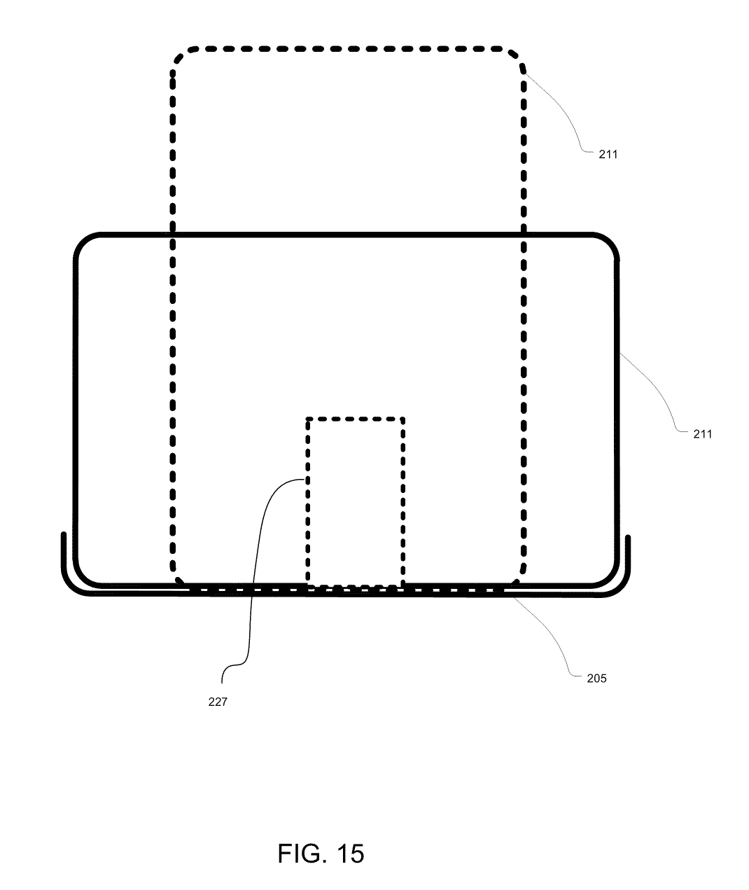

FIG. 15 is a front view of an embodiment illustrating the mobile device protector 205, including the stand or support structure, that may be used to support the mobile device 211 either in landscape mode or portrait mode. It will be appreciated that mobile devices 211 may be used in various modes depending upon the orientation of the device relative to the user. The protector 205 may include a plurality of stands or support structures 225 and 227 disclosed herein is uniquely designed to accommodate both landscape and portrait modes. Thus, no matter the orientation of the mobile device 211, the plurality of stands disclosed herein may be utilized by the user without departing from the scope of the disclosure.

In the foregoing Detailed Description, various features of the disclosure are grouped together in a single embodiment for the purpose of streamlining the disclosure. This method of disclosure is not to be interpreted as reflecting an intention that the claimed disclosure requires more features than are expressly recited in each claim. Rather, as the disclosure reflects, inventive aspects lie in less than all features of a single foregoing disclosed embodiment.

It is to be understood that the above-described arrangements are only illustrative of the application of the principles of the disclosure. Numerous modifications and alternative arrangements may be devised by those skilled in the art without departing from the spirit and scope of the disclosure and the disclosure is intended to cover such modifications and arrangements. Thus, while the disclosure has been shown in the drawings and described above with particularity and detail, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A mobile device protector comprising:
a form factor similar to a mobile device to be protected wherein the protector is configured such that the mobile device nests into the protector;
a shell constructed of a substantially rigid material;
wherein said shell is configured to receive and cover substantially the face of the mobile device;
wherein the protector is attached to mobile device through a friction fit;
a shock absorbing isolating layer; and
a cut out or recessed portion configured to allow access to electric connectors.

2. The mobile device protector of claim 1, wherein said shock absorbing layer is configured to prevent the scratching and breaking of the screen of the mobile device.

3. The mobile device protector of claim 1, wherein said substantially rigid material is aluminum.

4. The mobile device protector of claim 1, wherein said shock absorbing layer is neoprene or foam.

5. The mobile device protector of claim 1, wherein said protector is configured to receive the back of the mobile device while the mobile device is in use.

6. A mobile device protector having stand functionality comprising:
a form factor similar to a mobile device to be protected wherein the protector is configured such that the mobile device nests into the protector;
a shell constructed of a substantially rigid material;
wherein said shell is configured to receive and cover substantially the face of the mobile device;
wherein the protector is attached to mobile device through a friction fit;
a shock absorbing isolating layer;
a cut out or recessed portion configured to allow access to electric connectors;
a stand slot configured for receiving a folding stand;
wherein said folding stand comprises:
a first support structure having a first length such that when said support structure is rotated into a deployed position a first support angle is provided;
wherein said first support structure comprises a substantially rigid portion rotatably connected to said shell at a first end and connected to a flexible portion at an opposing second end;
wherein said flexible portion's unencumbered end is attached to said shell;
a second support structure having a second length such that when said support structure is rotated into a deployed position a second support angle is provided.

7. The mobile device protector of claim 6, wherein said second support structure nests withing said first support structure.

8. The mobile device protector of claim 6, wherein said shock absorbing layer is configured to prevent the scratching and breaking of the screen of the mobile device.

9. The mobile device protector of claim 6, wherein said substantially rigid material is aluminum.

10. The mobile device protector of claim 6, wherein said shock absorbing layer is neoprene or foam.

11. The mobile device protector of claim 6, wherein said protector is configured to receive the back of the mobile device while the mobile device is in use.

12. The mobile device protector of claim 6, wherein said first support structure rotates where it connects to said shell.

13. A mobile device protector having stand functionality and peripheral functionality comprising:
a form factor similar to a mobile device to be protected wherein the protector is configured such that the mobile device nests into the protector;
a shell constructed of a substantially rigid material;
wherein said shell is configured to receive and cover substantially the face of the mobile device;
wherein the protector is attached to mobile device during use through a friction fit;
a shock absorbing isolating layer;
a cut out or recessed portion configured to allow access to electric connectors;
a stand slot configured for receiving a folding stand;
wherein said folding stand comprises:
a first support structure having a first length such that when said support structure is rotated into a deployed position a first support angle is provided;
wherein said first support structure comprises a substantially rigid portion rotatably connected to said shell at a first end and connected to a flexible portion at an opposing second end;
wherein said flexible portion's unencumbered end is attached to said shell;
a second support structure having a second length such that when said support structure is rotated into a deployed position a second support angle is provided;
an input device for entering commands and data into the mobile device.

14. The mobile device protector of claim 13, wherein said input device is a keyboard attached to said mobile device protector.

15. The mobile device protector of claim 14, further comprising cable routing within the shock absorbing layer for an electronic cable configured to connect said keyboard to said mobile device.

16. The mobile device protector of claim 6, wherein said first support structure rotates where it connects to said shell.

17. The mobile device protector of claim 13, wherein said shock absorbing layer is configured to prevent the scratching and breaking of the screen of the mobile device.

18. The mobile device protector of claim 13, wherein said substantially rigid material is aluminum.

19. The mobile device protector of claim 13, wherein said shock absorbing layer is neoprene or foam.

20. The mobile device protector of claim 13, wherein said protector is configured to receive the back of the mobile device while the mobile device is in use.

21. The mobile device protector of claim 13, wherein said shock absorbing layer is configured to accommodate said input device by having a slot therein shaped for receiving said input device.

22. A system for a protected mobile device comprising:
a mobile device;
a form factor similar to a mobile device to be protected wherein the protector is configured such that the mobile device nests into the protector;
a shell constructed of a substantially rigid material;
wherein said shell is configured to receive and cover substantially the face of the mobile device;
wherein the protector is attached to mobile device during use through a friction fit;
a shock absorbing isolating layer;
a cut out or recessed portion configured to allow access to electric connectors;
a stand slot configured for receiving a folding stand;
wherein said folding stand comprises:
a first support structure having a first length such that when said support structure is rotated into a deployed position a first support angle is provided;
wherein said first support structure comprises a substantially rigid portion rotatably connected to said shell at a first end and connected to a flexible portion at an opposing second end;
wherein said flexible portion's unencumbered end is attached to said shell;
a second support structure having a second length such that when said support structure is rotated into a deployed position a second support angle is provided;
an input device for entering commands and data into the mobile device.
